(19) United States
(12) Patent Application Publication
(10) Pub. No.: US 2005/0185487 A1
(43) Pub. Date: Aug. 25, 2005

(54) Digitally controlled oscillator circuit

(76) Inventor: Alexander Belitzer, Meunchen (DE)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/053,530

(22) Filed: Feb. 8, 2005

(30) Foreign Application Priority Data
Feb. 9, 2004 (DE) 102004006311.7

(51) Int. Cl. G11C 7/00

(52) U.S. Cl. 365/202

(57) ABSTRACT

A digitally controlled oscillator circuit for generating a signal at variable frequency is provided. The circuit has a data input for a digital control word and a capacitive circuit for varying the variable frequency of the signal. The capacitive circuit comprises a control input for a control signal and its total capacitance varies on the basis of the control signal. The data input and the control input have a mapping device coupled between them. This device is set up such that it ascertains the control signal from the digital control word.

### PRIORITY

This application claims foreign priority to German application number 102004006311.7 filed Feb. 9, 2004.

### TECHNICAL FIELD OF THE INVENTION

The present invention relates to a digitally controlled oscillator circuit for generating a signal, where the signal has a variable frequency.

### BACKGROUND OF THE INVENTION

In a data transmission system, it is often desirable to provide a signal at a variable frequency, with the frequency of the signal being able to be set by a digital control device. This applies to clock signals or to carrier or modulation signals in the data transmission system, for example. The frequency should be able to be set within a prescribed bandwidth of the spectrum with a desired level of accuracy. To generate the signal, digitally controlled oscillator circuits are used. The frequency of the signal generated by the oscillator circuit is controlled using a digital control word via a variable capacitance in this case. The variable capacitance is connected in series with a resonant circuit or with a quartz oscillator. The frequency f of the oscillator circuit is nonlinearly dependent on the total capacitance value C of the variable capacitance, in line with the following rule:
f˜C^{-1/2} (1)
In practice, linear actuation of the frequency by the digital control word is desirable. To this end, the variable capacitance is provided in the form of a capacitive field which is made up of different single capacitors. For each settable capacitance value, a corresponding single capacitor is therefore defined. To set the capacitance value, an appropriate single capacitor is selected and connected, while the other single capacitors are decoupled. This means that the number N of single capacitors required is very large. By way of example, a 13-bit control word requires a number N=2¹³=8192 different single capacitors. This makes implementing N different single capacitors with respective different sizes a complex matter.

The capacitive field is also required to exhibit a necessary degree of monotony for the frequency dependency on the digital control word. This variable is expressed by a differential nonlinearity, also referred to as DNL. This variable corresponds to the change in the frequency as a function of the change in the control word by one bit. The DNL shows the quality of the capacitive field. At the same time, the differential nonlinearity DNL indicates the accuracy with which the frequency can be set.

### SUMMARY OF EMBODIMENTS OF THE INVENTION

The problem for the present invention is to provide a digital oscillator circuit which is simple to implement and which makes it easier to meet a demand on the differential nonlinearity.

The problem is solved by a digitally controlled oscillator circuit for generating a signal which has the following features: a data input for a digital control word, a capacitive circuit for varying the variable frequency of the signal, which circuit has a control input for a control signal and whose total capacitance varies on the basis of the control signal, and a mapping device, coupled between the data input and the control input, for mapping the digital control word onto the control signal in order to achieve a defined dependency on the digital control word for the total capacitance.

By mapping the digital control word onto the control signal, the value of the total capacitance is controlled by the digital control word. In this case, the dependency of the total capacitance on the digital control word is essentially defined by the mapping between the control signal and the digital control word.

Advantageously, the dependency of the total capacitance on the digital control word can be matched to the demands of the digital oscillator circuit. Viewed externally, the control of the oscillator circuit when viewed externally is independent of the dependency of the total capacitance on the control signal. This allows the oscillator circuit to be optimized in terms of two aspects.

First, the capacitive circuit can be chosen such that implementation thereof is simplified as far as possible.

By ascertaining the control signal from the digital control word using the mapping device, it is additionally possible to influence the differential nonlinearity and to optimize it according to the properties of the capacitive circuit.

A further advantage is that altering a component of the oscillator circuit, such as a quartz oscillator, does not require the capacitive field coupled thereto to be redefined. Particularly when an integrated semiconductor circuit is designed such that individual components are in different forms for different versions, the present invention eliminates the need for the capacitive field to be changed in complex fashion. Only the mapping device needs to be adapted as appropriate.

In one development of the oscillator circuit, the mapping device has a programmable arithmetic and logic unit or a microprocessor. Calculation of the control signal from the digital control word may thus be matched to various demands in variable fashion.

Typically, a mapping device of this type has a memory which is coupled to the programmable arithmetic and logic unit or to the microprocessor. This memory stores, by way of example, coefficients which are needed for ascertaining or calculating the control signal from the digital control word. This applies particularly to the case in which a calculation is performed by an algebraic function or a polynomial, which have coefficients.

In one alternative development of the oscillator circuit, the distortion device has a memory which contains a respective association between a value for the control signal and a value for the digital control word. This makes it possible to dispense with a complex arithmetic and logic unit. The association can also be altered. Clearly, the memory corresponds to a table memory or a so-called “look-up table”.

Typically, the capacitive field has a parallel circuit comprising capacitors which can be coupled or decoupled on the basis of the control signal. The total capacitance is therefore obtained in simple fashion from the sum of the capacitors which have been connected. It is possible to connect various capacitances in the capacitive field in parallel to provide a particular total capacitance. This significantly reduces the number of capacitances required. Particularly in integrated components which comprise a digitally controlled oscillator circuit based on the invention, the required surface area on the semiconductor and hence manufacturing costs can be reduced.

In one refinement, the capacitive circuit has at least one varactor which can be connected or decoupled on the basis of the control signal.

In one possible development, the capacitors are chosen such that the total capacitance is linearly dependent on a binary control signal. The number of capacitances required is reduced from 2N to N. A dependency of this type is achieved through binary staggering of the capacitances, for example, such that the capacitive field has a parallel circuit comprising capacitors, where the i-th capacitor has the capacitance value 2(i 1) C0. This provides binary coding for the settable total capacitance. Alternatively, other codings are conceivable. In the text below, a parallel circuit of this type is referred to as a binary-coded capacitive field.

If the capacitances have essentially the same capacitance value, then one bit of the control signal can alter the total capacitance by this capacitance value, for example.

In one embodiment, the mapping device is set up such that the control signal is calculated from the control word using an algebraic function.

The coefficients of an algebraic function of this type are provided by the chosen capacitive field, the resonant circuit used and by external constraints. An algebraic dependency allows a simple relationship to be produced between the control signal and the digital control word, which permits a simple design for the distortion apparatus and particularly for an arithmetic and logic unit in the mapping apparatus. In this case, the calculation can be performed by a logic circuit or by a programming code.

Preferably, the mapping device is set up such that the frequency is linearly dependent on the control word. This simplifies, in particular, the actuation of the digitally controlled oscillator circuit, because the digital control word can be regarded directly as a value for a frequency which has been set.

### BRIEF DESCRIPTION OF THE DRAWINGS

The invention is explained in more detail below using exemplary embodiments with reference to the drawings, in which:

FIG. 1 shows an exemplary, digitally controlled oscillator circuit with a quartz oscillator;

FIG. 2 shows a quartz oscillator and the equivalent circuit diagram for a quartz oscillator;

FIG. 3 shows the schematic illustration of a capacitive circuit controlled by a digital control word;

FIG. 4 shows an example of a dependency on the digital control word for the control signal in line with a first embodiment;

FIG. 5 shows an example of a dependency on a total capacitance of the capacitive circuit for a differential nonlinearity in the inventive oscillator circuit; and

FIG. 6 shows an example of a dependency on the digital control word for a frequency change in the inventive oscillator circuit in the case of different embodiments of the invention.

### DETAILED DESCRIPTION OF EMBODIMENTS OF THE INVENTION

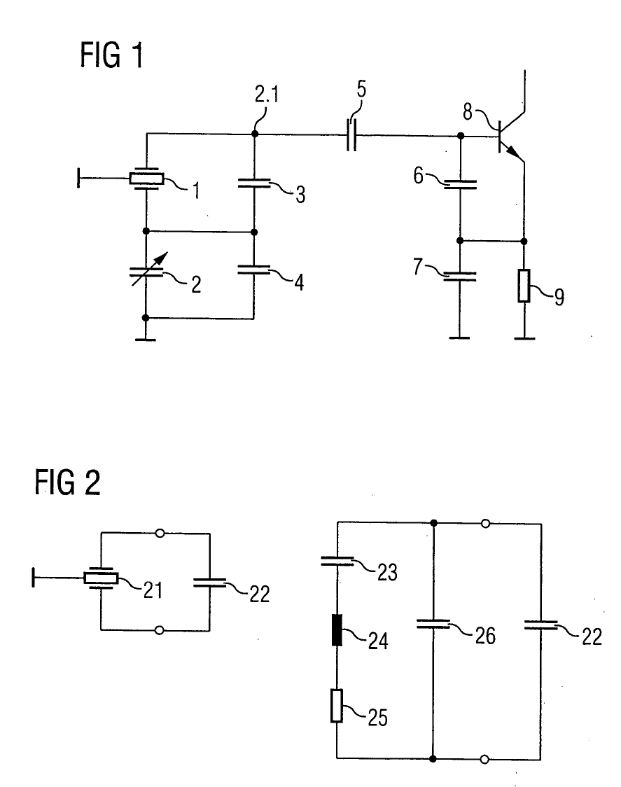

FIG. 1 shows an exemplary, digitally controlled oscillator circuit with a quartz oscillator 1. The quartz oscillator 1 is connected in series with a capacitive circuit 2, a first output of the quartz oscillator 1 being connected to a ground connection via the capacitive circuit 2. The effect of the capacitive circuit 2 corresponds to that of a variable capacitance. It may be in the form of a capacitive field comprising capacitors which are connected in parallel. A respective switching element allows single capacitors to be coupled or decoupled in the capacitive field, which means that the total capacitance of the capacitive circuit 2 can be altered by a control signal. Preferably, it is a binary-coded capacitive field, so that the control signal is linearly related to the corresponding value of the total capacitance.

The quartz oscillator 1 has a first capacitor 3 connected in parallel with it. Similarly, the capacitive circuit 2 has a second capacitor 4 connected in parallel with it.

The quartz oscillator 1 together with the capacitive circuit 2, the first capacitor 3 and the second capacitor 4 form, in line with the arrangement described, a resonant circuit with a resonant frequency which can be altered using the total capacitance of the capacitive circuit 2. This resonant circuit is coupled to the base connection of a bipolar transistor 8 via a node 2.1 at the second output of the quartz oscillator 1 by means of a third capacitor 5. The emitter connection of the transistor 8 is connected to ground via a resistor 9. A fourth capacitor 6 is coupled between the base connection and the emitter connection of the transistor. The resistor 9 has a fifth capacitor 7 connected in parallel with it. The fourth capacitor 6 and the fifth capacitor 7 provide smoothing for the signal which is output on the collector connection of the transistor 8.

The coupling of the resonant circuit to the base connection of the transistor 8 causes the latter to turn its collector/emitter path on and off periodically at the resonant frequency prescribed by the capacitive circuit 2. If the collector connection is connected to a constant voltage potential, then a periodic signal can be tapped off thereon which oscillates at the resonant frequency of the resonant circuit. The signal level is stipulated by the voltage applied and by the size of the resistor 9.

FIG. 2 shows a quartz oscillator and the equivalent circuit diagram for a quartz oscillator. The left-hand circuit diagram shows a quartz oscillator 21 which is connected in parallel with a sixth capacitor 22. This parallel circuit is shown in the left-hand circuit diagram as an equivalent circuit diagram. The quartz oscillator 21 corresponds to a resonant circuit which has a series circuit comprising a seventh capacitor 23, an impedance or a coil 24 and a nonreactive resistor element 25, said series circuit being connected in parallel with an eighth capacitor 26.

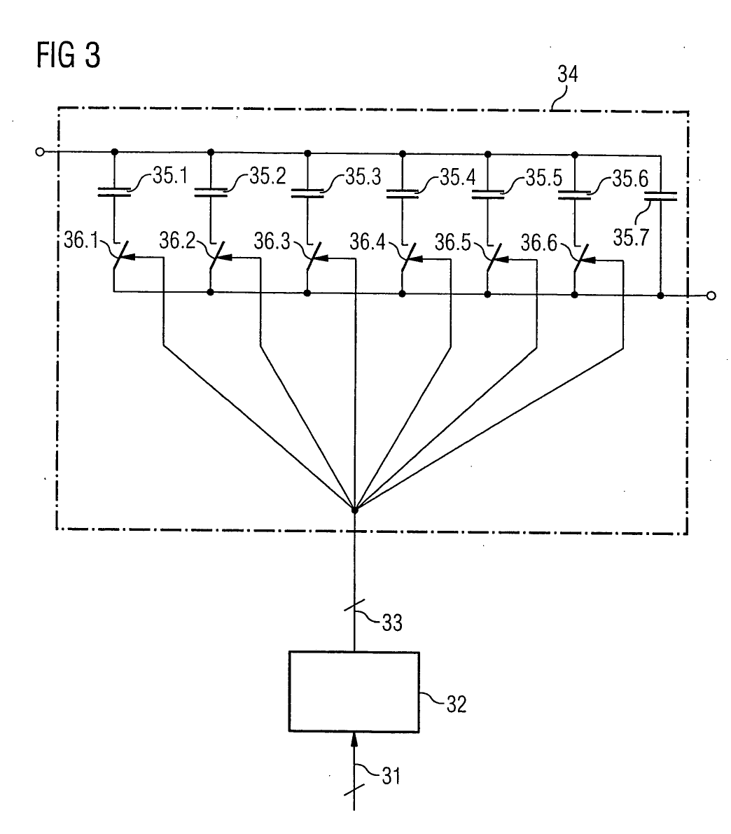

FIG. 3 shows a schematic illustration of a capacitive circuit 34 controlled by a digital control word. The capacitive circuit 34 is one possible embodiment of the capacitive circuit 2 shown in FIG. 1. The digital control word is input into a mapping device 32 via a parallel or serial data input 31. The mapping device 32 is coupled to the capacitive circuit 34 via a parallel control input 33. The control input 33 is used by the mapping device 32 to provide the capacitive circuit with a control signal ascertained on the basis of the digital control word. The capacitive circuit 34 has a ninth capacitor 35.7. Connected in parallel with the ninth capacitor 35.7 are a multiplicity of pairs respectively comprising a capacitor 35.1-35.6, which can be connected in parallel, and a switching element 36.1-36.6. The switching element 36.1-36.6 can be used to connect the corresponding connectable capacitor 35.1-35.6 in parallel with the ninth capacitor 35.7 or to decouple it therefrom. The setting of the switching elements 36.1-36.6 therefore allows the total capacitance of the capacitive circuit 34 to be set. The setting of the switching elements 36.1-36.6 is determined by the control signal in this case. In the example shown, the control signal has a digital word of 6 bits.

In one preferred embodiment, the capacitor field is in binary-coded form. In this case, the ninth capacitor 35.7 has a capacitance with the value C_{MIN}. This is the minimum capacitance of the capacitive circuit 34. The capacitors 35.1-35.6 which can be connected in parallel have different capacitances. In this case, the smallest capacitance has a size Cₛ, the next largest capacitance has the value 2Cₛ, the next largest capacitance has the value 4Cₛ and so on, up to the largest capacitance with the value 2⁶Cₛ. This provides the total capacitance of the capacitive circuit 34 with binary coding. The total capacitance can thus be changed on the basis of the control signal in steps of C₀ starting from an initial value C_{MIN}.

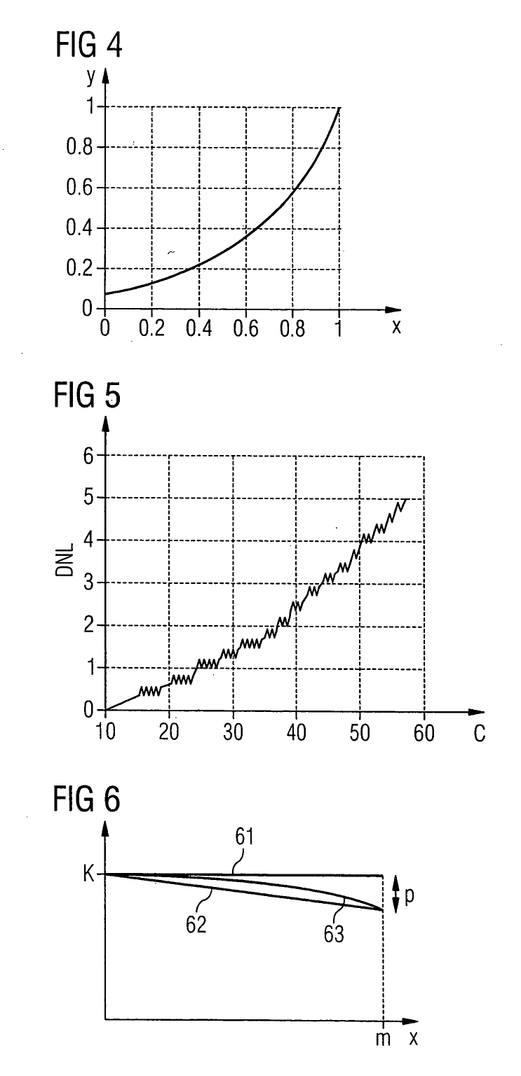

FIG. 4 shows, by way of example, a dependency on the digital control word for the control signal in line with a first embodiment of the inventive oscillator circuit. The illustration plots the control signal X on the abscissa over the digital control word X on the ordinate. To simplify the illustration, the text below assumes continuous values for the digital control word X and for the control signal. However, it will be pointed out that the two variables are actually discrete values, preferably in a binary representation, such as using a bit word.

The dependency between the digital control word X and the control signal Y is chosen such that a frequency F, generated by the oscillator circuit, and the digital control word X have a linear relationship which is defined by a frequency shift F₀ and a resolution frequency K which corresponds to the slope
F=KX+F₀. (2)

In order to produce this linear relationship, the digital control word X and the control signal Y have the following algebraic relationship:

$$Y = \overline{v} α + \frac{β}{γ + X} . \qquad ( 3 )$$

In this case, the coefficients α, β and γ are dependent on the design of the resonant circuit. For the circuits shown in FIG. 1 and FIG. 2, the following relationships are obtained for the coefficients

$$α = 1 - \frac{{C}_{vm}}{d {C}_{v}} + \frac{( - {C}_{vs} ( {C}_{x} + {C}_{0} ) - {C}_{2} {C}_{sum} )}{{C}_{sum} d {C}_{v}} ; \\ β = - \frac{( {C}_{0} + {C1}_{nom} ) {C}_{vs}^{2} {C}_{1} 1 e6}{K ( 2 {C}_{0} + 2 {C1}_{nom} + {C}_{1} ) d {C}_{v} {C}_{sum}^{2}} ; \\ γ = 1 - \frac{{F}_{0}}{K} - \frac{1 e6}{K} + \frac{1 e6}{K A} + \frac{1 {e6C}_{1}}{2 K A {C}_{sum}} . \qquad ( 5 )$$

In this case,
Cₛᵤₘ=C₀+C_{X}+C_{VS} (7)
and

$$A = 1 + \frac{{C}_{1}}{2 ( {C}_{0} + {C1}_{nom} )} \qquad ( 8 )$$

are true.

In this context, the incoming system variables are specified as follows:
Cᵥₘ is the minimum capacitance of the capacitive circuit 2 or 34;
dCᵥ is the step size which can be used to change the capacitance of the capacitive circuit 2 or 34 by altering the least significant bit; in the case in FIG. 3 it would correspond to the value Cₛ. It is obtained from the series circuit comprising the third capacitor 5, the fourth capacitor 6 and the fifth capacitor 7, which are shown in FIG. 1.
Cᵥₛ is the total capacitance of the resonant circuit as seen at node 2.1 in FIG. 1;
C_{X} is the capacitance of the first capacitor 3;
C₀ is the capacitance of the eighth capacitor 26;
C₁ is the capacitance of the seventh capacitor 23;
C₂ is the capacitance of the second capacitor 4, and
C1ₙₒₘ is the capacitance of the sixth capacitor 22.

This specification of the coefficients is a specific formulation for the exemplary embodiments shown in FIG. 1 and FIG. 2. In other embodiments of the resonant circuit, they are adapted as appropriate.

FIG. 5 shows an example of a dependency on a total capacitance C of the capacitive circuit for a differential nonlinearity DNL in the inventive oscillator circuit. In this case, the abscissa plots the differential nonlinearity DNL over the total capacitance C on the ordinate.

FIG. 6 shows an example of a dependency on the digital control word for a frequency change in the inventive oscillator circuit in the case of different embodiments of the invention. To this end, the representation on the abscissa plots a change in the frequency relative to a change in the digital control word X by one bit. The ordinate shows the digital control word X with a maximum value m. The graph shows three curves. A first curve 61 shows the case of a linear relationship between the frequency and the digital control word X. The first curve 61 has the value K over the entire range of the values of the digital word. A second curve 62 and a third curve 63 show another profile. For a minimum value of the digital control word X, both curves, the second curve 62 and the third curve 63, have the value K. For the maximum value m of the digital control word X, both curves have the value (K-p). Hence, the increase in the frequency is reduced at greater values of the digital control word. The reduction in the frequency increase is essentially determined by the differential magnitude p. This is particularly advantageous when stringent demands are placed on the differential nonlinearity DNL.

The second curve 62 corresponds to a particular algebraic relationship between the control signal Y and the digital control word X which, besides the coefficients α, β and γ already shown, is also dependent on the maximum digital control word m and on the differential frequency p

$$Y = α + \frac{β}{γ - X ( 1 - \frac{p}{m} X )} . \qquad ( 9 )$$

Similarly, the third curve 63 corresponds to a particular algebraic relationship between the control signal Y and the digital control word X which, besides the coefficients α, β and γ already shown, is also dependent on the maximum digital control word m and on the differential frequency p

$$Y = α + \frac{β}{γ - X ( 1 - \frac{p}{2 m} X - \frac{p}{2 {m}^{2}} {X}^{2} )} . \qquad ( 10 )$$

Rather than calculating the control signal from the digital control word, the mapping apparatus may also have a “look-up table”. A table of this type contains the values of the control signal in association with the corresponding values of the digital control word. The calculation has already been performed in order to allow this association. A table of this type will be defined on the basis of the number of values of the digital control word and will normally comprise a few bits.

Regardless of this, the control of the digital oscillator circuit will always proceed in the same way. The mapping device ascertains the control signal from a digital control word which has been input. This is done through calculation by means of an arithmetic and logic unit or a microprocessor or by looking it up in a “look-up table”. The total capacitance changes on the basis of the control signal. A change in the digital control word results in a new value for the control signal and hence for the total capacitance. This also alters the frequency of the signal generated, which means that it can be set variably.

1. A digitally controlled oscillator circuit for generating a signal having a variable frequency, said circuit comprising:
a data input for a digital control word,
a capacitive circuit to vary the variable frequency of the signal, said capacitive circuit having a control input for a control signal, wherein said capacitive circuit has a total capacitance that varies on the basis of the control signal, and
a mapping device, coupled between the data input and the control input, to map the digital control word onto the control signal to obtain a defined dependency on the digital control word for the total capacitance.

2. A digitally controlled oscillator circuit according to claim 1, wherein the mapping device comprises a programmable arithmetic and logic unit or a microprocessor.

3. A digitally controlled oscillator circuit according to claim 2, wherein the mapping device comprises a memory coupled to the programmable arithmetic and logic unit or to the microprocessor.

4. A digitally controlled oscillator circuit according to claim 1, wherein the mapping device comprises a memory containing a respective association between a value for the control signal and a value for the digital control word.

5. A digitally controlled oscillator circuit according to claim 1, wherein the capacitive circuit comprises a parallel circuit comprising capacitors which can be coupled or decoupled on the basis of the control signal.

6. A digitally controlled oscillator circuit according to claim 1, wherein the capacitive circuit comprises at least one varactor which can be coupled or decoupled on the basis of the control signal.

7. A digitally controlled oscillator circuit according to claim 5, wherein the capacitors are chosen such that the total capacitance is linearly dependent on a binary control signal.

8. A digitally controlled oscillator circuit according to claim 6, wherein the capacitors are chosen such that the total capacitance is linearly dependent on a binary control signal.

9. A digitally controlled oscillator circuit according to claim 5, wherein the capacitors have essentially the same capacitance values.

10. A digitally controlled oscillator circuit according to claim 6, wherein the capacitors have essentially the same capacitance values.

11. A digitally controlled oscillator circuit according to claim 1, wherein the mapping device is configured such that the control signal is calculated from the control word using an algebraic function.

12. A digitally controlled oscillator circuit according to claim 9, wherein the mapping device is configured such that the frequency is linearly dependent on the control word.
